(19) United States
(12) Patent Application Publication
(10) Pub. No.: US 2024/0421044 A1
(43) Pub. Date: Dec. 19, 2024

(54) Die-Attach Fillet Height Reduction

(71) Applicant: Wolfspeed, Inc., Durham, NC (US)

(72) Inventors: Daniel Ginn Richter, Raleigh, NC (US); Afshin Dadvand, Durham, NC (US)

(21) Appl. No.: 18/336,376

(22) Filed: Jun. 16, 2023

(51) Int. Cl. H01L 23/495; H01L 21/52

(52) U.S. Cl. CPC H01L 23/49513; H01L 21/52

(57) ABSTRACT

Semiconductor packages are provided. In one example, a semiconductor package includes a submount and a semiconductor die attached to the submount using a die-attach material. The semiconductor die includes a sidewall having at least one fillet reduction feature. The at least one fillet reduction feature is configured to limit a fillet height of the die-attach material along the sidewall of the semiconductor die.

### FIELD

Example aspects of the present disclosure relate generally to semiconductor devices.

### BACKGROUND

Semiconductor devices, including power semiconductor devices based on wide bandgap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide bandgap semiconductor die, may need to be attached to a conductive lead frame for use in a discrete power semiconductor package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or can be learned from the description, or can be learned through practice of the embodiments.

One example embodiment of the present disclosure is directed to a semiconductor package. The semiconductor package includes a submount and a semiconductor die attached to the submount using a die-attach material. The semiconductor die has a sidewall comprising at least one fillet reduction feature. The at least one fillet reduction feature is configured to limit a fillet height of the die-attach material along the sidewall of the semiconductor die.

Another example embodiment of the present disclosure is directed to a semiconductor die. The semiconductor die includes a first surface and a second surface opposing the first surface. The semiconductor die includes a sidewall defined between the first surface and the second surface. The sidewall includes at least one fillet reduction feature. The at least one fillet reduction feature is configured to limit a fillet height of a die-attach material along the sidewall of the semiconductor die.

Another example embodiment of the present disclosure is directed to a method of forming a semiconductor package. The method includes performing a dicing process on a semiconductor wafer to form at least one fillet reduction feature on a sidewall of a semiconductor die. The fillet reduction feature is configured to limit a fillet height of a die-attach material along the sidewall of the semiconductor die.

Another embodiment of the present disclosure is directed to a semiconductor package. The semiconductor package includes a submount and a semiconductor die attached to the submount using a die-attach material. The die-attach material comprises a wettable die-attach material. A fillet height of the die-attach material along a surface of a sidewall of the semiconductor die is in a range of about 5% to about 50% of a thickness of the semiconductor die.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example device with a semiconductor die attached to a submount using a die-attach material according to example embodiments of the present disclosure;

FIG. 2 depicts an example semiconductor die attached to a submount with die-attach wetting up a sidewall of the semiconductor;

FIG. 3 depicts an example semiconductor die attached to a submount according to example embodiments of the present disclosure;

FIG. 4 depicts an example semiconductor die attached to a submount according to example embodiments of the present disclosure;

FIG. 5 depicts an example semiconductor die attached to a submount according to example embodiments of the present disclosure;

FIG. 6 depicts an example semiconductor die attached to a submount according to example embodiments of the present disclosure;

FIG. 7 depicts an example semiconductor die attached to a submount according to example embodiments of the present disclosure;

FIG. 8 depicts an example semiconductor die attached to a submount according to example embodiments of the present disclosure;

FIG. 9 depicts an example semiconductor die attached to a submount according to example embodiments of the present disclosure;

FIG. 10 depicts an example semiconductor package according to example embodiments of the present disclosure;

FIG. 11 depicts a flow chart diagram of an example method according to example embodiments of the present disclosure;

FIG. 12 depicts a flow chart diagram of an example method according to example embodiments of the present disclosure; and

FIG. 13 depicts an illustrative example of the example method of FIG. 12 according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to semiconductor packages (e.g., discrete semiconductor packages and power modules) for use in semiconductor applications and other electronic applications. In some embodiments, semiconductor packages can include one or more semiconductor die having at least one semiconductor device. For instance, the semiconductor die can include, e.g., wide bandgap semiconductor devices, silicon carbide-based semiconductor devices (e.g., MOSFETs, Schottky diodes), Group III nitride-based semiconductor devices (e.g., high electron mobility transistor (HEMT) devices), etc.

In some semiconductor packages, one or more semiconductor die can be attached to a submount (e.g., lead frame) using a die-attach material. Various types of die-attach materials can be used to bond the one or more semiconductor die to the submount such as, for instance, metal sintering die-attach (e.g., silver (Ag) or copper (Cu)) and conductive adhesive die-attach. In some instances, these die-attach material options may result in the die-attach material wetting up the sidewall of the semiconductor die, thereby resulting in a die-attach fillet covering some, or all, of the sidewall of the semiconductor die.

As the die-attach material (e.g., die-attach fillet) approaches a topside of the semiconductor die, the electric field increases. Moreover, the likelihood of an electrical short caused by the die-attach material migration likewise increases. Thus, controlling how far the die-attach fillet wets up the sidewall of the semiconductor die (e.g., controlling die-attach fillet height) may be important in semiconductor manufacturing. Furthermore, as semiconductor die become both larger in size and thinner in thickness, controlling the die-attach fillet height becomes increasingly more difficult.

Solutions for controlling die-attach fillet height may include die-attach material selection and process control (e.g., dispense volume, dispense pattern, die-bond parameters). For larger semiconductor die, this may limit the use of metal sintering die-attach (e.g., silver (Ag) or copper (Cu)) materials and/or conductive adhesive die-attach materials. Solutions for controlling die-attach material fillet height regardless of die-attach material type would be desirable.

Accordingly, example aspects of the present disclosure are directed to a semiconductor package having a semiconductor die attached to a submount using a die-attach material. The semiconductor die can include a sidewall having at least one fillet reduction feature that is configured to limit a fillet height of the die-attach material along the sidewall of the semiconductor die. In some embodiments, the semiconductor die can include at least one fillet reduction feature on each of two sides of the semiconductor die. In some embodiments, the semiconductor die can include at least one fillet reduction feature on each of four sides (or more) of the semiconductor die.

Example aspects of the present disclosure are further directed to a multi-step dicing process to actively control and reduce the die-attach fillet length up a sidewall of a semiconductor die. The dicing process can be performed on a semiconductor wafer to form at least one fillet reduction feature on the sidewall of the semiconductor die. The semiconductor die can then be bonded to a submount with a die-attach material. In this way, the fillet reduction feature can limit a fillet height of the die-attach material along the sidewall of the semiconductor die.

As used herein, the term “bonding” or “bonding process” refers to causing a transition of a material from a first form to a second form. A bonding process may or may not require attaching a component to the material. Sintering, reflow, annealing, curing, exposing to light, and exposing to ultraviolet light are examples of bonding processes and are encompassed by the term “bonding” or “bonding process” in the disclosure and in the claims.

Aspects of the present disclosure provide a number of technical effects and benefits. For instance, semiconductor packages according to example aspects of the present disclosure may be fabricated such that a sidewall of a semiconductor die includes at least one fillet reduction feature. In this way, die-attach fillet height and sidewall wetting can be controlled, thereby providing more control over the electrical characteristics of the semiconductor package. Furthermore, example aspects of the present disclosure allow for the use of metal sintering die-attach (e.g., silver (Ag) or copper (Cu)) materials and/or conductive adhesive die-attach materials on large, thin semiconductor die.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

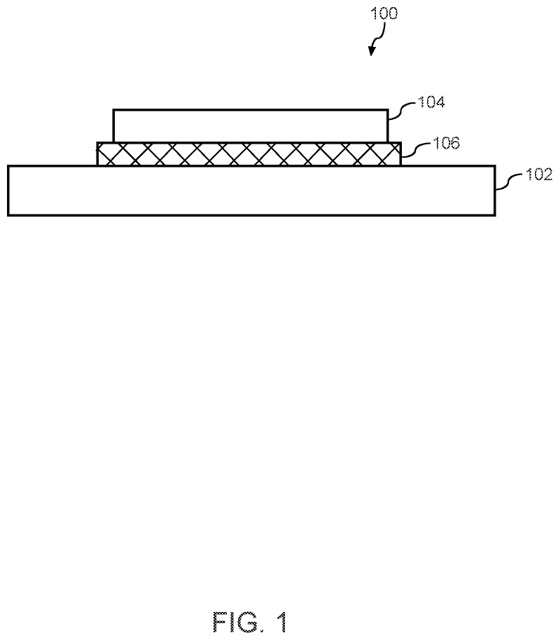

FIG. 1 depicts a cross-sectional view of at least a portion of a semiconductor package 100 according to example embodiments of the present disclosure. The semiconductor package 100 may include a submount 102. The submount 102 may be, for instance, a lead frame or other supporting structure of a wide bandgap power semiconductor device, such as a silicon carbide-based semiconductor power module or discrete package. The submount 102 may be, for instance, a copper submount 102 or may include other suitable conducting material(s).

The semiconductor package 100 may include a semiconductor die 104. The semiconductor die 104 may include one or more devices, such as one or more of a wide variety of power devices available for different applications including, for example, power switching devices and/or power amplifiers. In some examples, the semiconductor die 104 may include one or more transistor devices, such as field effect transistors (FETs) devices, including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistor devices, etc. In some embodiments, the semiconductor die 104 may include one or more diodes (e.g., Schottky diodes, light emitting diodes, etc.).

In some embodiments, the semiconductor die 104 may be fabricated from wide bandgap semiconductor materials (e.g., having a band gap greater than 1.40 eV). For high power, high temperature, and/or high frequency applications, devices formed in wide bandgap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities.

Aspects of the present disclosure are discussed with reference to wide bandgap semiconductors for purposes of illustration and discussion. Those of ordinary skill in the art, using the disclosures provided herein, will understand that the die-attach materials according to example embodiments of the present disclosure may be used with any semiconductor material or other material without deviating from the scope of the present disclosure.

The semiconductor die 104 may be attached to the submount 102 using a die-attach material 106. The die-attach material 106 may include, for instance, solder, paste, sintered metal, etc. For instance, the die-attach material 106 may include a sintered metal such as, e.g., copper sintered metal and/or silver sintered metal.

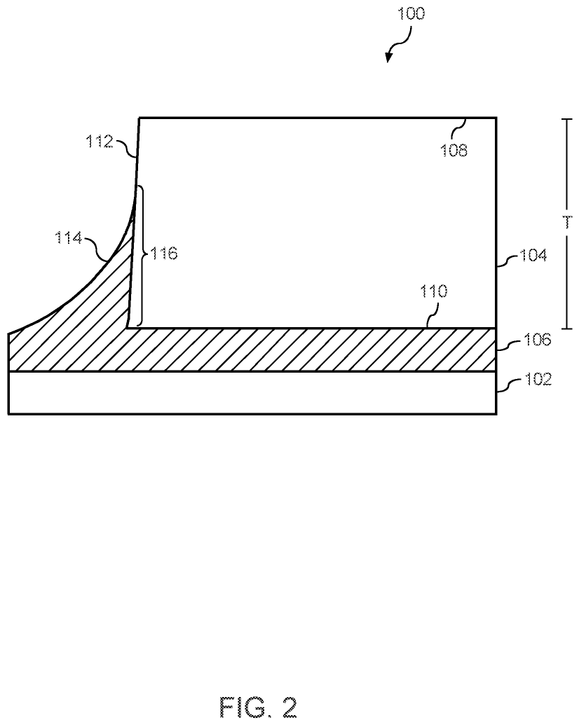

FIG. 2 depicts a close-up view of a sidewall of the example semiconductor die 104 discussed above with reference to FIG. 1. As shown, the semiconductor die 104 may include a first surface 108 (e.g., topside surface 108) and a second surface 110 (e.g., bottom-side surface 110) opposing the first surface 108. Furthermore, the semiconductor die 104 may include a sidewall 112 defined between the first surface 108 and the second surface 110.

As noted above, the semiconductor die 104 may be attached to the submount 102 (e.g., lead frame) using the die-attach material 106. In some embodiments, the die-attach material 106 may be a wettable die-attach material 106. For instance, the die-attach material 106 may be a sintered metal such as, for instance, sintered-silver and/or sintered-copper. In this way, the semiconductor die 104 may be in mechanical, thermal, and/or electrical contact with the submount 102.

During attachment of the semiconductor die 104 to the submount 102, the die-attach material 106 may wet up some (or all) of the sidewall 112 of the semiconductor die 104, thereby defining a die-attach fillet 114 having a fillet height 116. The fillet height 116 is defined the height the die-attach fillet wets up the sidewall of the semiconductor die. As noted above, as the fillet 114 approaches the first surface 108 of the semiconductor die 104 (e.g., as the fillet height 116 increases), the electric field may increase. Furthermore, the likelihood of an electrical short caused by the fillet 114 likewise increases.

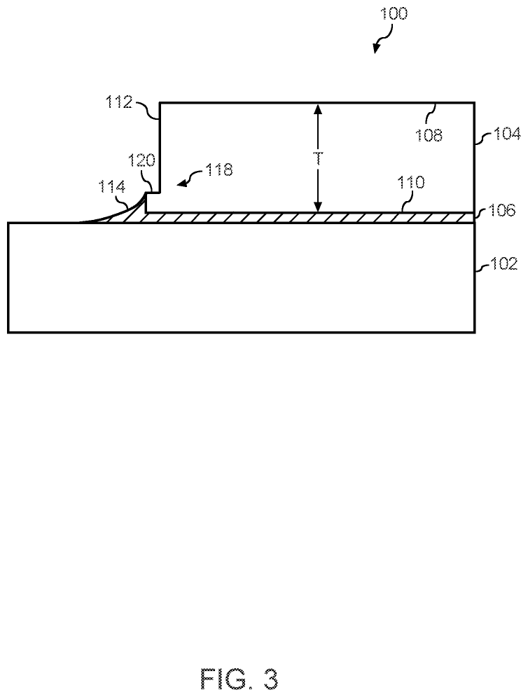

According to example aspects of the present disclosure, a semiconductor die may include a fillet reduction feature in the sidewall. Example semiconductor die 104 having a fillet reduction feature(s) in the sidewall are illustrated in FIGS. 3-9.

More particularly, FIGS. 3-9 depict example semiconductor die 104 having fillet reduction feature(s) according to example embodiments of the present disclosure. FIGS. 3-9 are provided for purposes of illustration and discussion. Those of ordinary skill in the art, using the disclosures provided herein, will understand that aspects of the present disclosure may be used in a variety of devices and/or applications without deviating from the scope of the present disclosure.

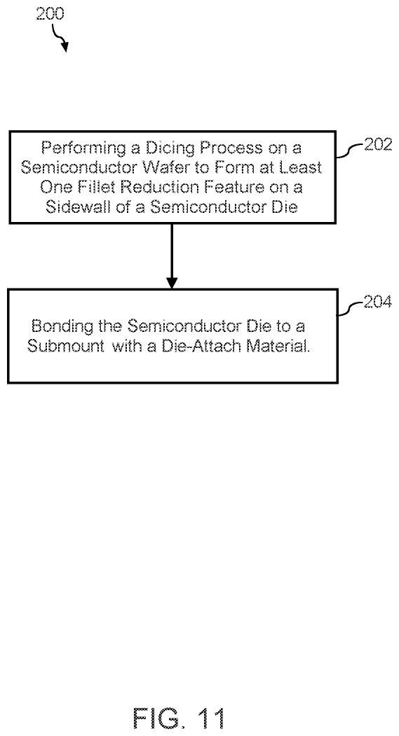

FIG. 3 depicts an example semiconductor die 104 having a sidewall profile having at least one fillet reduction feature 118. More particularly, the semiconductor die 104 may include a multi-cut dicing-defined feature fillet reduction feature 118 in the sidewall 112. The multi-cut dicing process that defines the fillet reduction feature 118 will be discussed in more detail with respect to FIGS. 11-13. The fillet reduction feature 118 may be configured to limit a fillet height of the die-attach fillet 114 along the sidewall 112 of the semiconductor die 104. The sidewall profile of the semiconductor die 104 may include a stepped surface profile. In the example of FIG. 3, the fillet reduction feature 118 may include a step surface 120 that faces away from the submount 102.

According to example aspects of the present disclosure, the fillet reduction feature 118 may be configured such that the fillet height of the die-attach material 106 along a surface of the sidewall 112 is in a range of about five percent (5%) to about fifty percent (50%) of a thickness T of the semiconductor die 104. Furthermore, in some embodiments, the fillet reduction feature 118 may be configured such that the fillet height of the die-attach material 106 along the surface of the sidewall 112 is in a range of about five percent (5%) to about twenty-five percent (25%) of the thickness T of the semiconductor die 104.

For instance, in some embodiments, the fillet reduction feature 118 may be configured to limit the height of the die-attach fillet 114 such that the fillet height along the sidewall 112 is approximately fifty percent (50%) or less of the thickness T of the semiconductor die 104. In such embodiments, the fillet reduction feature 118 may be located at a location in the sidewall 112 at a distance from the second surface 110 of approximately fifty percent (50%) or less of the thickness T of the semiconductor die 104.

In other embodiments, the fillet reduction feature 118 may be configured to limit the height of the fillet 114 such that the fillet height along the sidewall 112 is approximately twenty-five percent (25%) or less of the thickness T of the semiconductor die 104. In such embodiments, the fillet reduction feature 118 may be located at a location in the sidewall 112 at a distance from the second surface 110 of approximately twenty-five percent (25%) or less of the thickness T of the semiconductor die 104.

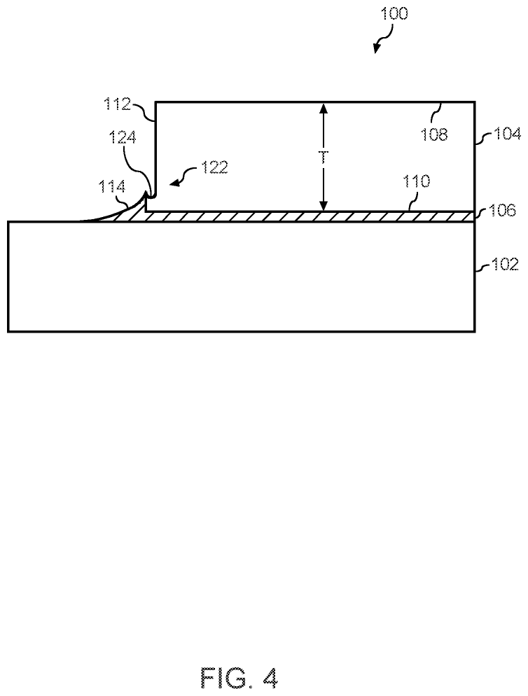

FIG. 4 depicts an example semiconductor die 104 having a sidewall profile having at least one fillet reduction feature 122. More particularly, the semiconductor die 104 may include a multi-cut dicing-defined feature fillet reduction feature 122 in the sidewall 112. The fillet reduction feature 122 may be configured to limit a height of the die-attach fillet 114 along the sidewall 112 of the semiconductor die 104. The sidewall profile of the semiconductor die 104 may include a stepped surface profile. In the example of FIG. 4, the fillet reduction feature 122 may include a non-planar indentation 124 that faces away from the submount 102. The non-planar indentation 124 may include a curved surface.

According to example aspects of the present disclosure, the fillet reduction feature 122 may be configured such that the fillet height of the die-attach material 106 along a surface of the sidewall 112 is in a range of about five percent (5%) to about fifty percent (50%) of a thickness T of the semiconductor die 104. Furthermore, in some embodiments, the fillet reduction feature 122 may be configured such that the fillet height of the die-attach material 106 along the surface of the sidewall 112 is in a range of about five percent (5%) to about twenty-five percent (25%) of the thickness T of the semiconductor die 104.

For instance, in some embodiments, the fillet reduction feature 122 may be configured to limit the height of the fillet 114 such that the fillet height along the sidewall 112 is approximately fifty percent (50%) or less of the thickness T of the semiconductor die 104. In such embodiments, the fillet reduction feature 122 may be located at a location in the sidewall 112 at a distance from the second surface 110 of approximately fifty percent (50%) or less of the thickness T of the semiconductor die 104.

In other embodiments, the fillet reduction feature 122 may be configured to limit the height of the fillet 114 such that the fillet height along the sidewall 112 is approximately twenty-five percent (25%) or less of the thickness T of the semiconductor die 104. In such embodiments, the fillet reduction feature 122 may be located at a location in the sidewall 112 at a distance from the second surface 110 of approximately twenty-five percent (25%) or less of the thickness T of the semiconductor die 104.

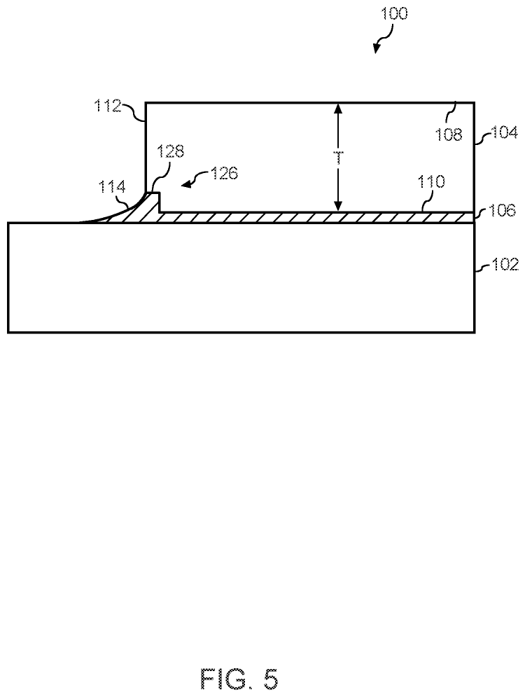

FIG. 5 depicts an example semiconductor die 104 having a sidewall profile having at least one fillet reduction feature 126. More particularly, the semiconductor die 104 may include a multi-cut dicing-defined feature fillet reduction feature 126 in the sidewall 112. The fillet reduction feature 126 may be configured to limit a height of the die-attach fillet 114 along the sidewall 112 of the semiconductor die 104. The sidewall profile of the semiconductor die 104 may include a stepped surface profile. In the example of FIG. 5, the fillet reduction feature 126 may include a step surface 128 that faces toward the submount 102.

According to example aspects of the present disclosure, the fillet reduction feature 126 may be configured such that the fillet height of the die-attach material 106 along a surface of the sidewall 112 is in a range of about five percent (5%) to about fifty percent (50%) of a thickness T of the semiconductor die 104. Furthermore, in some embodiments, the fillet reduction feature 126 may be configured such that the fillet height of the die-attach material 106 along the surface of the sidewall 112 is in a range of about five percent (5%) to about twenty-five percent (25%) of the thickness T of the semiconductor die 104.

For instance, in some embodiments, the fillet reduction feature 126 may be configured to limit the height of the fillet 114 such that the fillet height along the sidewall 112 is approximately fifty percent (50%) or less of the thickness T of the semiconductor die 104. In such embodiments, the fillet reduction feature 126 may be located at a location in the sidewall 112 at a distance from the second surface 110 of approximately fifty percent (50%) or less of the thickness T of the semiconductor die 104.

In other embodiments, the fillet reduction feature 126 may be configured to limit the height of the fillet 114 such that the fillet height along the sidewall 112 is approximately twenty-five percent (25%) or less of the thickness T of the semiconductor die 104. In such embodiments, the fillet reduction feature 126 may be located at a location in the sidewall 112 at a distance from the second surface 110 of approximately twenty-five percent (25%) or less of the thickness T of the semiconductor die 104.

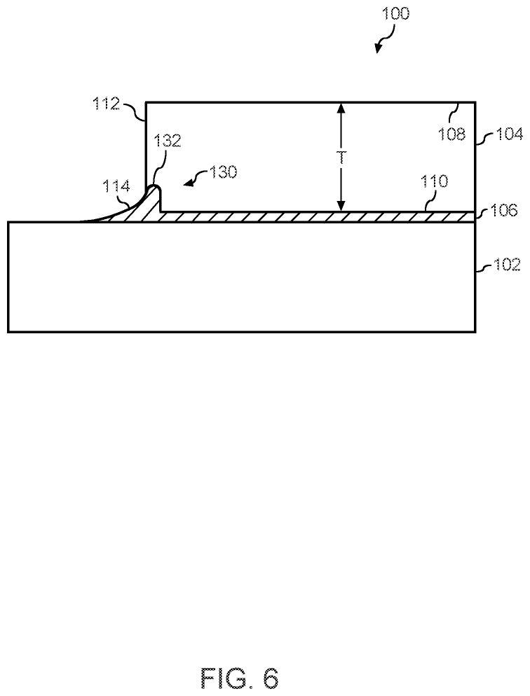

FIG. 6 depicts an example semiconductor die 104 having a sidewall profile having at least one fillet reduction feature 130. More particularly, the semiconductor die 104 may include a multi-cut dicing-defined feature fillet reduction feature 130 in the sidewall 112. The fillet reduction feature 130 may be configured to limit a height of the die-attach fillet 114 along the sidewall 112 of the semiconductor die 104. The sidewall profile of the semiconductor die 104 may include a stepped surface profile. In the example of FIG. 6, the fillet reduction feature 130 may include a non-planar indentation 132 that faces towards the submount 102.

According to example aspects of the present disclosure, the fillet reduction feature 130 may be configured such that the fillet height of the die-attach material 106 along a surface of the sidewall 112 is in a range of about five percent (5%) to about fifty percent (50%) of a thickness T of the semiconductor die 104. Furthermore, in some embodiments, the fillet reduction feature 130 may be configured such that the fillet height of the die-attach material 106 along the surface of the sidewall 112 is in a range of about five percent (5%) to about twenty-five percent (25%) of the thickness T of the semiconductor die 104.

For instance, in some embodiments, the fillet reduction feature 130 may be configured to limit the height of the fillet 114 such that the fillet height along the sidewall 112 is approximately fifty percent (50%) or less of the thickness T of the semiconductor die 104. In such embodiments, the fillet reduction feature 130 may be located at a location in the sidewall 112 at a distance from the second surface 110 of approximately fifty percent (50%) or less of the thickness T of the semiconductor die 104.

In other embodiments, the fillet reduction feature 130 may be configured to limit the height of the fillet 114 such that the fillet height along the sidewall 112 is approximately twenty-five percent (25%) or less of the thickness T of the semiconductor die 104. In such embodiments, the fillet reduction feature 130 may be located at a location in the sidewall 112 at a distance from the second surface 110 of approximately twenty-five percent (25%) or less of the thickness T of the semiconductor die 104.

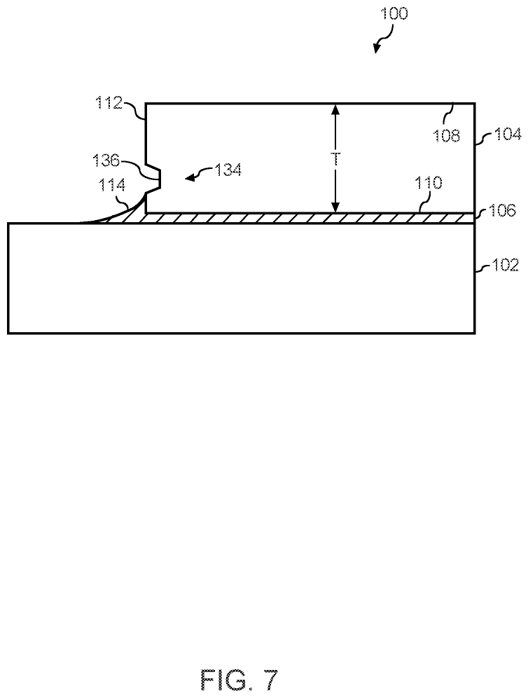

FIG. 7 depicts an example semiconductor die 104 having a sidewall profile having at least one fillet reduction feature 134. The fillet reduction feature 134 may be configured to limit a height of the die-attach fillet 114 along the sidewall 112 of the semiconductor die 104. In the example of FIG. 7, the fillet reduction feature 134 may include a recess 136 in the sidewall 112.

According to example aspects of the present disclosure, the fillet reduction feature 134 may be configured such that the fillet height of the die-attach material 106 along a surface of the sidewall 112 is in a range of about five percent (5%) to about fifty percent (50%) of a thickness T of the semiconductor die 104. Furthermore, in some embodiments, the fillet reduction feature 134 may be configured such that the fillet height of the die-attach material 106 along the surface of the sidewall 112 is in a range of about five percent (5%) to about twenty-five percent (25%) of the thickness T of the semiconductor die 104.

For instance, in some embodiments, the fillet reduction feature 134 may be configured to limit the height of the fillet 114 such that the fillet height along the sidewall 112 is approximately fifty percent (50%) or less of the thickness T of the semiconductor die 104. In such embodiments, the fillet reduction feature 134 may be located at a location in the sidewall 112 at a distance from the second surface 110 of approximately fifty percent (50%) or less of the thickness T of the semiconductor die 104.

In other embodiments, the fillet reduction feature 134 may be configured to limit the height of the fillet 114 such that the fillet height along the sidewall 112 is approximately twenty-five percent (25%) or less of the thickness T of the semiconductor die 104. In such embodiments, the fillet reduction feature 134 may be located at a location in the sidewall 112 at a distance from the second surface 110 of approximately twenty-five percent (25%) or less of the thickness T of the semiconductor die 104.

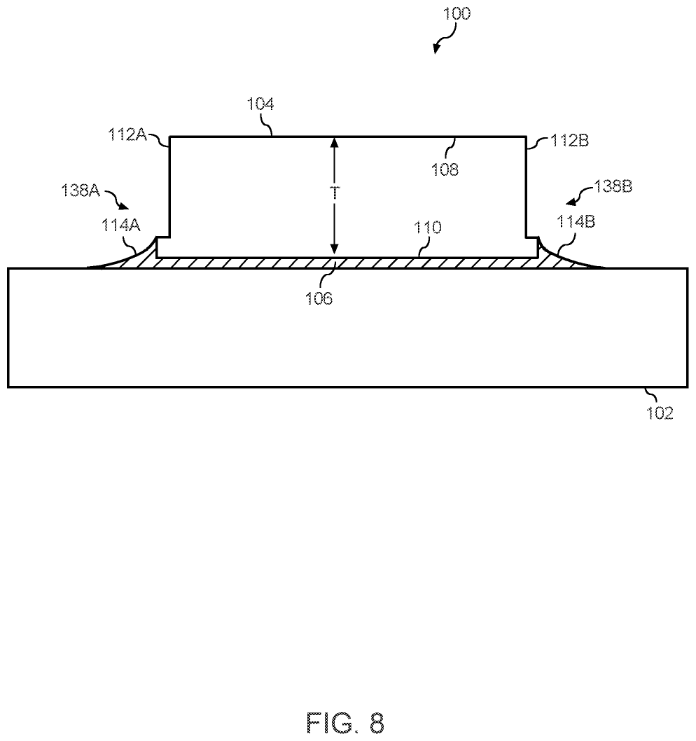

FIG. 8 depicts an example semiconductor die 104 having a sidewall profile having fillet reduction features 138A, 138B. More particularly, the semiconductor die 104 may include multi-cut dicing-defined features fillet reduction features 138A and 138B in the sidewalls 112A and 112B, respectively. The fillet reduction feature 138A may be configured to limit a height of the die-attach fillet 114A along the sidewall 112A, and the fillet reduction feature 138B may be configured to limit a height of the die-attach fillet 114B along the sidewall 112B. In the example of FIG. 8, the semiconductor package 100 may include fillet reduction features 138A, 138B on each of two sides (e.g., defined by sidewalls 108A, 108B) of the semiconductor die 104.

According to example aspects of the present disclosure, fillet reduction features 138A, 138B may be configured such that the fillet heights of the die-attach material 106 along a surface of the sidewalls 112A, 112B are in a range of about five percent (5%) to about fifty percent (50%) of a thickness T of the semiconductor die 104. Furthermore, in some embodiments, fillet reduction features 138A, 138B may be configured such that the fillet heights of the die-attach material 106 along the surface of the sidewalls 112A, 112B are in a range of about five percent (5%) to about twenty-five percent (25%) of the thickness T of the semiconductor die 104.

For instance, in some embodiments, fillet reduction features 138A, 138B may be configured to limit the heights of the fillets 114A, 114B such that the fillet heights along the sidewalls 112A, 112B are approximately fifty percent (50%) or less of the thickness T of the semiconductor die 104. In such embodiments, fillet reduction features 138A, 138B may be located at a location in the sidewalls 112A, 112B at a distance from the second surface 110 of approximately fifty percent (50%) or less of the thickness T of the semiconductor die 104.

In other embodiments, fillet reduction features 138A, 138B may be configured to limit the heights of the fillets 114A, 114B such that the fillet heights along the sidewalls 112A, 112B are approximately twenty-five percent (25%) or less of the thickness T of the semiconductor die 104. In such embodiments, fillet reduction features 138A, 138B may be located at a location in the sidewalls 112A, 112B at a distance from the second surface 110 of approximately twenty-five percent (25%) or less of the thickness T of the semiconductor die 104.

It should be noted that, although depicted in a similar manner as fillet reduction feature 118 discussed above with reference to FIG. 3, the fillet reduction features 138A, 138B can be any of the fillet reduction features discussed herein without deviating from the scope of the present disclosure.

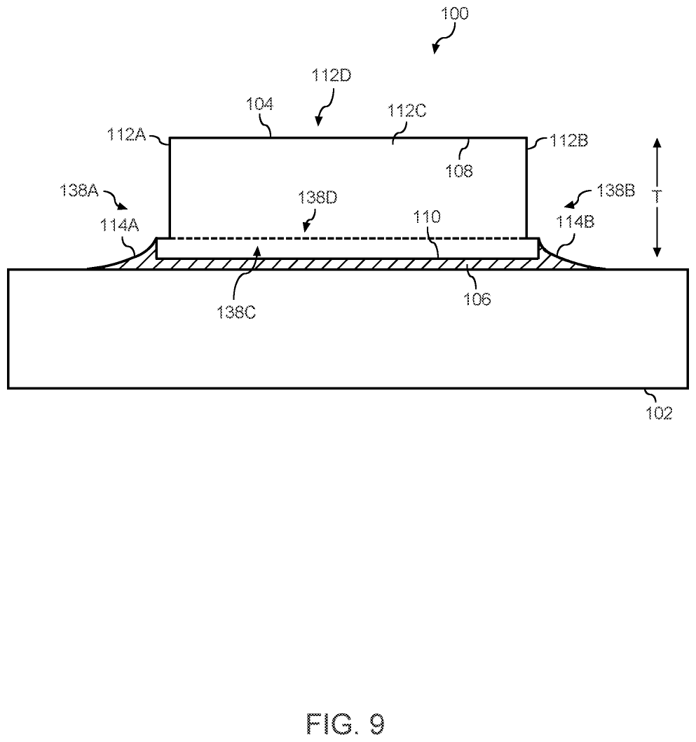

FIG. 9 depicts an example semiconductor die 104 having a sidewall profile having fillet reduction features 138A, 138B, 138C, 138D. More particularly, the semiconductor die 104 may include multi-cut dicing-defined features fillet reduction features 138A-138D in the sidewalls 112A-112D, respectively. The fillet reduction feature 138A may be configured to limit a height of the die-attach fillet 114A along the sidewall 112A, the fillet reduction feature 138B may be configured to limit a height of the die-attach fillet 114B along the sidewall 112B, the fillet reduction feature 138C may be configured to limit a height of the die-attach fillet 114C along the sidewall 112C, and the fillet reduction feature 138D may be configured to limit a height of the die-attach fillet 114D along the sidewall 112D. In the example of FIG. 9, the semiconductor package 100 may include fillet reduction features 138A, 138B, 138C, 138D on each of four sides (e.g., defined by sidewalls 108A, 108B, 108C, 108D) of the semiconductor die 104.

According to example aspects of the present disclosure, fillet reduction features 138A, 138B, 138C, 138D may be configured such that the fillet heights of the die-attach material 106 along a surface of the sidewalls 112A, 112B, 112C, 112D are in a range of about five percent (5%) to about fifty percent (50%) of a thickness T of the semiconductor die 104. Furthermore, in some embodiments, fillet reduction features 138A, 138B, 138C, 138D may be configured such that the fillet heights of the die-attach material 106 along the surface of the sidewalls 112A, 112B, 112C, 112D are in a range of about five percent (5%) to about twenty-five percent (25%) of the thickness T of the semiconductor die 104.

For instance, in some embodiments, fillet reduction features 138A, 138B, 138C, 138D may be configured to limit the heights of the fillets 114A, 114B, 114C, 114D such that the fillet heights along the sidewalls 112A, 112B, 112C, 112D are approximately fifty percent (50%) or less of the thickness T of the semiconductor die 104. In such embodiments, fillet reduction features 138A, 138B, 138C, 138D may be located at a location in the sidewalls 112A, 112B, 112C, 112D at a distance from the second surface 110 of approximately fifty percent (50%) or less of the thickness T of the semiconductor die 104.

In other embodiments, fillet reduction features 138A, 138B, 138C, 138D may be configured to limit the heights of the fillets 114A, 114B, 114C, 114D such that the fillet heights along the sidewalls 112A, 112B, 112C, 112D are approximately twenty-five percent (25%) or less of the thickness T of the semiconductor die 104. In such embodiments, fillet reduction features 138A, 138B, 138C, 138D may be located at a location in the sidewalls 112A, 112B, 112C, 112D at a distance from the second surface 110 of approximately twenty-five percent (25%) or less of the thickness T of the semiconductor die 104.

It should be noted that, although depicted in a similar manner as fillet reduction feature 118 discussed above with reference to FIG. 3, the fillet reduction features 138A, 138B, 138C, 138D can be any of the fillet reduction features discussed herein without deviating from the scope of the present disclosure.

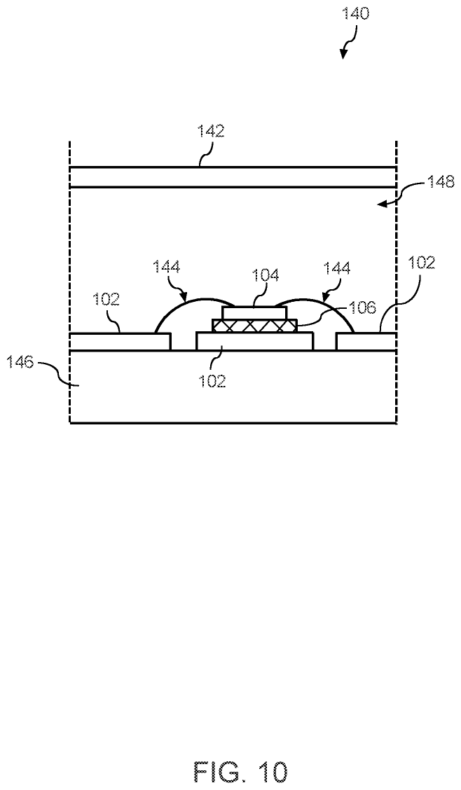

FIG. 10 depicts an example semiconductor package 140 including a semiconductor die attached to a submount according to example embodiments of the present disclosure. As shown, semiconductor package 140 may include the submount 102, semiconductor die 104, and die-attach material 106 as discussed above with reference to FIGS. 1-9. FIG. 10 is provided for purposes of illustration and discussion. Those of ordinary skill in the art, using the disclosures provided herein, will understand that aspects of the present disclosure may be used in a variety of devices and/or applications without deviating from the scope of the present disclosure.

The semiconductor package 140 may be, for instance, a power module. The semiconductor package 140 may include a housing 142. The semiconductor package 140 may include the conductive submount 102 (e.g., a patterned conductive substrate) on which a semiconductor die 104 containing one or more power devices (e.g., transistors, diodes, etc.) is attached using the die-attach material 106 according to example embodiments of the present disclosure. The die-attach material 106 may provide a thermal, mechanical, and electrical connection between the semiconductor die 104 and the conductive submount 102. In some embodiments, the semiconductor die 104 may also be connected to the conductive submount 102 using wire bonds 144. The conductive submounts 102 may be mounted on a base layer 146 (e.g., an insulating layer). An encapsulating material 148 (e.g., inert gel) may fill the space between the semiconductor die 104 and the housing 142.

FIG. 11 depicts a flow chart diagram of an example method 200 according to example embodiments of the present disclosure. FIG. 11 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At (202), the method 200 may include performing a dicing process on a semiconductor wafer to form at least one fillet reduction feature on a sidewall of a semiconductor die. More particularly, the semiconductor wafer may be diced in order to form at least one fillet reduction feature configured to prevent sidewall wetting. In some embodiments, the dicing process may be performed on a frontside surface of the semiconductor wafer. In other embodiments, the dicing process may be performed on a backside surface of the semiconductor wafer.

As noted above, the semiconductor die may include one or more wide bandgap semiconductor devices. The semiconductor die may further include one or more silicon carbide-based semiconductor devices such as, e.g., MOSFETs, Schottky diodes, etc. Even further, the semiconductor die may include one or more Group III nitride-based semiconductor devices such as, e.g., high-electron-mobility transistors (HEMTs).

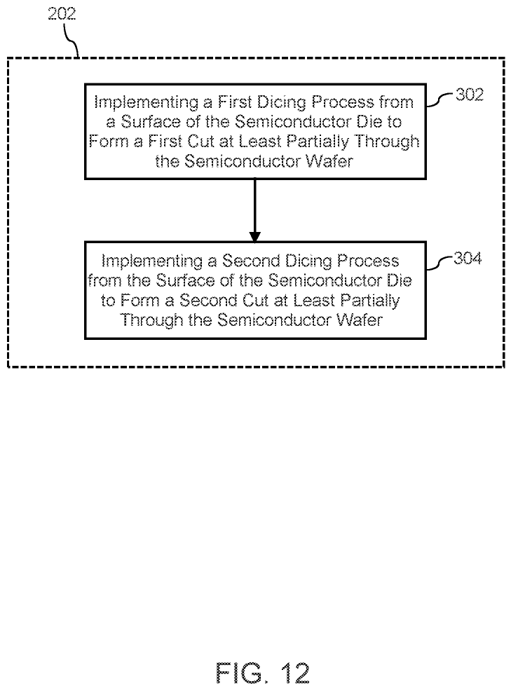

As an illustrative example, FIG. 12 depicts a flow chart diagram of an example method for performing the dicing process at (202). FIG. 12 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

Referring to FIG. 12, at (302), performing the dicing process at (202) may include implementing a first dicing process from a surface of the semiconductor die to form a first cut at least partially through the semiconductor wafer. As noted above, in some embodiments, the first dicing process may be performed from a frontside surface of the semiconductor wafer. In other embodiments, the first dicing process may be performed from a backside surface of the semiconductor wafer.

Furthermore, the first dicing process may be performed by a cutting device (e.g., tool) having a wide-blade flat-tip profile. For instance, a saw-based cutting device (e.g., dicing saw) may be used in the first dicing process to cut at least partially through the semiconductor wafer to form the first cut. In this way, the first cut may include a saw-based cut, and the first dicing process may be a saw-based dicing process (e.g., mechanical sawing). Additionally, the first cut may be associated with a first width.

Referring still to FIG. 12, at (304), performing the dicing process at (202) may further include implementing a second dicing process from the surface of the semiconductor die to form a second cut at least partially through the semiconductor wafer. Similar to the first dicing process, in some embodiments, the second dicing process may be performed from the frontside surface of the semiconductor wafer. In other embodiments, the second dicing process may be performed from the backside surface of the semiconductor wafer.

Furthermore, the second dicing process may be performed with a cutting device (e.g., cutting tool) having a thinner profile than the cutting device used to perform the first dicing process. For instance, a laser-based cutting device may be used in the second dicing process to cut at least partially through the semiconductor wafer to form the second cut. In this way, the second cut may include a laser-based cut, and the second dicing process may be a laser-based dicing process (e.g., stealth dicing, thermal laser separation (TLS)). Additionally, the second cut may be associated with a second width that is different from the first width. For instance, in some embodiments, the first width associated with the first cut may be larger than the second width associated with the second cut.

Referring again to FIG. 11 at (204), the method 200 may include bonding the semiconductor die to a submount with a die-attach material. As noted above, the at least one fillet reduction feature formed at (202) may be configured to limit a fillet height of the die-attach material along the sidewall of the semiconductor die. It should be noted that the at least one fillet reduction feature may include at least one fillet reduction feature on each of two sides of the semiconductor die and/or at least one fillet reduction feature on each of four sides of the semiconductor die.

Furthermore, the fillet reduction feature may include a stepped surface profile in the sidewall of the semiconductor die. As noted above, the stepped surface profile may include a step surface in the sidewall of the semiconductor die. For instance, as shown in FIGS. 4 and 6, the fillet reduction feature may include a step surface in the sidewall. The step surface may face away from the submount (FIG. 3) and/or towards the submount (FIG. 5).

The stepped surface profile can further include a non-planar surface in the sidewall of the semiconductor die. For instance, as shown in FIGS. 4 and 6, the fillet reduction feature may include a non-planar surface having one or more indentations in the sidewall. The indentations may face away from the submount (FIG. 4) and/or towards the submount (FIG. 6).

In other embodiments, such as that shown in FIG. 7, the fillet reduction feature may include a recess in the sidewall of the semiconductor die.

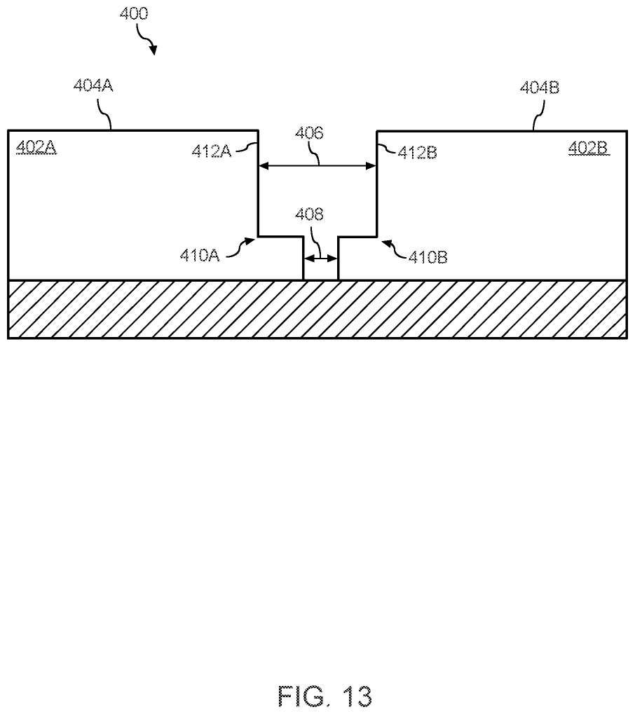

FIG. 13 depicts an illustrative example of the multi-cut dicing process discussed above with reference to FIGS. 11 and 12. As noted above, the example multi-cut dicing process may be performed on a semiconductor wafer 400 to form a first semiconductor die 402A and a second semiconductor die 402B. The dicing process may be performed on a frontside surface of the semiconductor wafer 400 and/or a backside surface of the semiconductor wafer 400.

The dicing process may include a first dicing process (e.g., first dicing process discussed above with reference to (302)). The first dicing process may be implemented from a surface 404A, 404B of the semiconductor die 402A and 402B, respectively, to form a first cut at least partially through (but not extending entirely through) the semiconductor wafer 400. The first dicing process may be performed by any of the cutting devices discussed above with reference to FIG. 11 at (302). Furthermore, the first cut may be associated with a first width 406.

The dicing process may further include a second dicing process (e.g., second dicing process discussed above with reference to (304)). The second dicing process may be implemented from the surface 404A, 404B of the semiconductor die 402A and 402B, respectively, to form a second cut at least partially through the semiconductor wafer 400. The second dicing process may be performed by any of the cutting devices discussed above with reference to FIG. 11 at (304). Furthermore, the second cut may be associated with a second width 408 that is different from the first width 406. For instance, as shown, the first width 406 associated with the first cut may be larger than the second width 408 associated with the second cut.

As shown, the dicing process may be performed to form fillet reduction features 410A, 410B on semiconductor die 402A and 402B, respectively. More particularly, the fillet reduction features 410A, 410B may be formed on sidewalls 412A and 412B, respectively. It should be noted that, although fillet reduction features 410A and 410B are depicted in a similar manner as fillet reduction feature 118 discussed above with reference to FIG. 3, the dicing process can be performed to form any of the fillet reduction features discussed herein without deviating from the scope of the present disclosure.

Example aspects of the present disclosure are set forth below. Any of the below features or examples may be used in combination with any of the embodiments or features provided in the present disclosure.

One example embodiment of the present disclosure is directed to a semiconductor package. The semiconductor package includes a submount and a semiconductor die attached to the submount using a die-attach material. The semiconductor die has a sidewall comprising at least one fillet reduction feature. The at least one fillet reduction feature is configured to limit a fillet height of the die-attach material along the sidewall of the semiconductor die.

In some examples, the at least one fillet reduction feature comprises at least one fillet reduction feature on each of two sides of the semiconductor die.

In some examples, the at least one fillet reduction feature comprises at least one fillet reduction feature on each of four sides of the semiconductor die.

In some examples, the at least one fillet reduction feature comprises a stepped surface profile in the sidewall. In some examples, the stepped surface profile comprises a step surface.

In some examples, the step surface is a non-planar surface. In some examples, the step surface comprises one or more indentations.

In some examples, the step surface faces toward the submount. In some examples, the step surface faces away from the submount.

In some examples, the at least one fillet reduction feature comprises a recess in the sidewall.

In some examples, the at least one fillet reduction feature is a multi-cut dicing-defined feature in the sidewall.

In some examples, the fillet height of the die-attach material along the sidewall is about 50% or less of a thickness the semiconductor die. In some examples, the fillet height of the die-attach material along the sidewall is about 25% or less of a thickness the semiconductor die.

In some examples, the die-attach material comprises a wettable die-attach material. In some examples, the die-attach material comprises a sintered metal. In some examples, the sintered metal comprises silver or copper.

In some examples, the submount comprises a lead frame.

In some examples, the semiconductor die comprises a wide bandgap semiconductor device.

In some examples, the semiconductor die comprises a silicon carbide-based semiconductor device. In some examples, the semiconductor die comprises a silicon carbide-based MOSFET. In some examples, the semiconductor die comprises a silicon carbide-based Schottky diode.

In some examples, the semiconductor die comprises a Group III nitride-based semiconductor device. In some examples, the semiconductor die comprises a Group III nitride-based high electron mobility transistor.

In some examples, the semiconductor package further comprises an encapsulating material.

Another example embodiment of the present disclosure is directed to a semiconductor die. The semiconductor die includes a first surface and a second surface opposing the first surface. The semiconductor die includes a sidewall defined between the first surface and the second surface. The sidewall includes at least one fillet reduction feature. The at least one fillet reduction feature is configured to limit a fillet height of a die-attach material along the sidewall of the semiconductor die.

In some examples, the at least one fillet reduction feature comprises at least one fillet reduction feature on each of two sides of the semiconductor die.

In some examples, the at least one fillet reduction feature comprises at least one fillet reduction feature on each of four sides of the semiconductor die.

In some examples, the at least one fillet reduction feature comprises a stepped surface profile in the sidewall. In some examples, the stepped surface profile comprises a step surface.

In some examples, the step surface is a non-planar surface. In some examples, the step surface comprises one or more indentations.

In some examples, the step surface faces toward the first surface. In some examples, the step surface faces away from the first surface.

In some examples, the at least one fillet reduction feature comprises a recess in the sidewall.

In some examples, the at least one fillet reduction feature is a multi-cut dicing-defined feature in the sidewall.

In some examples, the at least one fillet reduction feature is at a location in the sidewall at a distance from the second surface of approximately 50% or less of a thickness of the semiconductor die. In some examples, the at least one fillet reduction feature is at a location in the sidewall at a distance from the second surface of approximately 25% or less of a thickness of the semiconductor die.

In some examples, the semiconductor die comprises a wide bandgap semiconductor device.

In some examples, the semiconductor die comprises a silicon carbide-based semiconductor device. In some examples, the semiconductor die comprises a silicon carbide-based MOSFET. In some examples, the semiconductor die comprises a silicon carbide-based Schottky diode.

In some examples, the semiconductor die comprises a Group III nitride-based semiconductor device. In some examples, the semiconductor die comprises a Group III nitride-based high electron mobility transistor.

Another example embodiment of the present disclosure is directed to a method of forming a semiconductor package. The method includes performing a dicing process on a semiconductor wafer to form at least one fillet reduction feature on a sidewall of a semiconductor die. The fillet reduction feature is configured to limit a fillet height of a die-attach material along the sidewall of the semiconductor die.

In some examples, the method further includes bonding the semiconductor die to a submount with a die-attach material.

In some examples, performing the dicing process includes implementing a first dicing process from a surface of the semiconductor die to form a first cut at least partially through the semiconductor wafer and implementing a second dicing process from the surface of the semiconductor die to form a second cut at least partially through the semiconductor wafer.

In some examples, the first cut is associated with a first width and the second cut is associated with a second width. The first width is different from the second width. In some examples, the first width is larger than the second width.

In some examples, the first cut comprises a saw-based cut and the second cut comprises a laser-based cut.

In some examples, the surface is a frontside of the semiconductor wafer. In some examples, the surface is a backside of the semiconductor wafer.

In some examples, the at least one fillet reduction feature comprises a stepped surface profile in the sidewall. In some examples, the stepped surface comprises a step surface.

In some examples, the step surface is a non-planar surface. In some examples, the step surface comprises one or more indentations.

In some examples, the step surface faces toward the submount. In some examples, the step surface faces away from the submount.

In some examples, the semiconductor die comprises a wide bandgap semiconductor device.

In some examples, the semiconductor die comprises a silicon carbide-based semiconductor device. In some examples, the semiconductor die comprises a silicon carbide-based MOSFET. In some examples, the semiconductor die comprises a silicon carbide-based Schottky diode.

In some examples, the semiconductor die comprises a Group III nitride-based semiconductor device. In some examples, the semiconductor die comprises a Group III nitride-based high electron mobility transistor.

Another embodiment of the present disclosure is directed to a semiconductor package. The semiconductor package includes a submount and a semiconductor die attached to the submount using a die-attach material. The die-attach material comprises a wettable die-attach material. A fillet height of the die-attach material along a surface of a sidewall of the semiconductor die is in a range of about 5% to about 50% of a thickness of the semiconductor die.

In some examples, a fillet height of the die-attach material along a surface of a sidewall of the semiconductor die is in a range of about 5% to about 25% of the thickness of the semiconductor die.

In some examples, the semiconductor die comprises a stepped surface profile in the sidewall. In some examples, the stepped surface comprises a step surface.

In some examples, the step surface is a non-planar surface. In some examples, the step surface comprises one or more indentations.

In some examples, the step surface faces toward the submount. In some examples, the step surface faces away from the submount.

In some examples, the semiconductor die comprises a recess in the sidewall.

In some examples, the semiconductor die comprises a multi-cut dicing defined feature in the sidewall.

In some examples, the die-attach material comprises a sintered metal. In some examples, the sintered metal comprises silver or copper.

In some examples, the submount comprises a lead frame.

In some examples, the semiconductor die comprises a wide bandgap semiconductor device.

In some examples, the semiconductor die comprises a silicon carbide-based semiconductor device. In some examples, the semiconductor die comprises a silicon carbide-based MOSFET. In some examples, the semiconductor die comprises a silicon carbide-based Schottky diode.

In some examples, wherein the semiconductor die comprises a Group III nitride-based semiconductor device. In some examples, the semiconductor die comprises a Group III nitride-based high electron mobility transistor.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor package, comprising:
a submount;
a semiconductor die attached to the submount using a die-attach material; and
wherein the semiconductor die has a sidewall, the sidewall comprising at least one fillet reduction feature, the at least one fillet reduction feature configured to limit a fillet height of the die-attach material along the sidewall of the semiconductor die.

2. The semiconductor package of claim 1, wherein the at least one fillet reduction feature comprises at least one fillet reduction feature on each of two sides of the semiconductor die.

3. The semiconductor package of claim 1, wherein the at least one fillet reduction feature comprises at least one fillet reduction feature on each of four sides of the semiconductor die.

4. The semiconductor package of claim 1, wherein the at least one fillet reduction feature comprises a stepped surface profile in the sidewall.

5. The semiconductor package of claim 4, wherein the stepped surface profile comprises a step surface.

6. The semiconductor package of claim 5, wherein the step surface is a non-planar surface.

7. The semiconductor package of claim 6, wherein the step surface comprises one or more indentations.

8. The semiconductor package of claim 5, wherein the step surface faces toward the submount.

9. The semiconductor package of claim 5, wherein the step surface faces away from the submount.

10. The semiconductor package of claim 1, wherein the at least one fillet reduction feature comprises a recess in the sidewall.

11. The semiconductor package of claim 1, wherein the at least one fillet reduction feature is a multi-cut dicing-defined feature in the sidewall.

12. The semiconductor package of claim 1, wherein the fillet height of the die-attach material along the sidewall is about 50% or less of a thickness the semiconductor die.

13. (canceled)

14. The semiconductor package of claim 1, wherein the die-attach material comprises a wettable die-attach material.

15. The semiconductor package of claim 14, wherein the die-attach material comprises a sintered metal.

16. The semiconductor package of claim 15, wherein the sintered metal comprises silver or copper.

17. (canceled)

18. The semiconductor package of claim 1, wherein the semiconductor die comprises a wide bandgap semiconductor device.

19. (canceled)

20. The semiconductor package of claim 1, wherein the semiconductor die comprises a silicon carbide-based MOSFET, a silicon carbide-based Schottky diode, or a Group III-nitride based high electron mobility transistor.

21-23. (canceled)

24. The semiconductor package of claim 1, further comprising an encapsulating material.

25. A semiconductor die, comprising:
a first surface;
a second surface opposing the first surface;
a sidewall defined between the first surface and the second surface; and
wherein the sidewall comprises at least one fillet reduction feature, the at least one fillet reduction feature configured to limit a fillet height of a die-attach material along the sidewall of the semiconductor die.

26-43. (canceled)

44. A method of forming a semiconductor package, comprising:
performing a dicing process on a semiconductor wafer to form at least one fillet reduction feature on a sidewall of a semiconductor die;
wherein the fillet reduction feature is configured to limit a fillet height of a die-attach material along the sidewall of the semiconductor die.

45-82. (canceled)
